(19) United States
(12) Patent Application Publication
(10) Pub. No.: US 2024/0370594 A1
(43) Pub. Date: Nov. 7, 2024

(54) DEVELOPMENT ASSISTANCE DEVICE, DEVELOPMENT ASSISTANCE METHOD, AND COMPUTER READABLE MEDIUM

(71) Applicant: Mitsubishi Electric Corporation, Tokyo (JP)

(72) Inventor: Satoshi NOGUCHI, Tokyo (JP)

(73) Assignee: Mitsubishi Electric Corporation, Tokyo (JP)

(21) Appl. No.: 18/774,636

(22) Filed: Jul. 16, 2024

Related U.S. Application Data
(63) Continuation of application No. PCT/JP2022/010468, filed on Mar. 10, 2022.

(51) Int. Cl. G06F 30/12

(52) U.S. Cl. CPC G06F 30/12

(57) ABSTRACT

A difference determination unit (22) determines whether there is a difference between source design data and destination design data associated with the source design data. The source design data is design data of a source device, which is a device used as a base. The destination design data is design data of a diverted device designed by diverting the source device. A data display unit (23) displays target data including the source design data, the destination design data, and derived data generated by making a change to the source design data. The data display unit (23) changes a display format of the target data, depending on whether it has been determined that there is a difference.

### CROSS REFERENCE TO RELATED APPLICATION

This application is a Continuation of PCT International Application No. PCT/JP2022/010468, filed on Mar. 10, 2022, which is hereby expressly incorporated by reference into the present application.

### TECHNICAL FIELD

The present disclosure relates to a technology to assist development using design data of other products.

### BACKGROUND ART

There are device manufacturers that develop devices that are constituents of a production facility. Among these device manufacturers, there are device manufacturers that customize base devices according to requirements of customers, and sell devices that are slightly different for each customer. Such device manufacturers design devices for each customer by customizing design data of base devices. Therefore, such device manufacturers create many pieces of similar design data.

Data management software called PLM is sometimes introduced to manage pieces of similar design data. PLM is an abbreviation for product life-cycle management. PLM manages relationships between and branches among pieces of design data.

PLM often provides a function of identifying the scope of impact of design changes and presenting it to a user. Patent Literature 1 describes a technology such that when a change is made to one drawing, drawings affected by that change are presented.

When delivering devices to customers, device manufacturers may also deliver derived data derived from design data of the devices. For example, an operation screen manual, which is derived data created based on the design of a device operation screen, may be delivered. An appearance diagram, which is derived data created based on 3D design data, may be delivered. D is an abbreviation for dimension.

### CITATION LIST

### Patent Literature

Patent Literature 1: JP 2021-140592 A

### SUMMARY OF INVENTION

### Technical Problem

Derived data is also often created by reusing past derived data. In this case, past design data and new design data are compared to extract differences, and modifications made to the past design data are identified. Then, the identified modifications are made to the past derived data to create new derived data.

New derived data may be created by extracting data from new design data and adding information as necessary. In this case, the relationship between past design data and past derived data is checked, and information to be included in the derived data is identified. Then, the new derived data is created by adding the identified information to the new design data.

There are many pieces of design data for one device. Therefore, it takes time and effort to identify modifications and so on for each piece of design data. Therefore, it takes time and effort to create derived data for delivery in a conventional manner.

An object of the present disclosure is to reduce the time and effort required to generate derived data.

### Solution to Problem

A development assistance device according to the present disclosure includes
a difference determination unit to determine whether there is a difference between source design data and destination design data associated with the source design data; and
a data display unit to display target data including the source design data, the destination design data, and derived data generated by making a change to the source design data, the data display unit changing a display format of the target data, depending on whether it has been determined by the difference determination unit that there is a difference.

### Advantageous Effects of Invention

In the present disclosure, source design data, destination design data, and derived data are displayed by changing a display format, depending on whether there is a difference between the source design data and the destination design data. As a result, when derived data for the destination design data is generated, it is possible to easily determine whether derived data for the source design data can be used without changes. If changes are necessary, the displayed source design data, destination design data, and derived data can be referred to. Therefore, the time and effort required to generate the derived data can be reduced.

### BRIEF DESCRIPTION OF DRAWINGS

FIG. 1 is a configuration diagram of a development assistance device 10 according to Embodiment 1;

FIG. 2 is a figure describing inputs to the development assistance device 10 according to Embodiment 1;

FIG. 3 is a figure describing destination design data 32 according to Embodiment 1;

FIG. 4 is a figure describing derived data 33 according to Embodiment 1;

FIG. 5 is a flowchart illustrating a flow of operation of the development assistance device 10 according to Embodiment 1;

FIG. 6 is a figure describing a method 1 of a data display process according to Embodiment 1;

FIG. 7 is a figure describing the method 1 of the data display process according to Embodiment 1;

FIG. 8 is a figure describing a method 2 of the data display process according to Embodiment 1;

FIG. 9 is a figure describing the method 2 of the data display process according to Embodiment 1;

FIG. 10 is a configuration diagram of the development assistance device 10 according to Variation 1;

FIG. 11 is a configuration diagram of the development assistance device 10 according to Embodiment 2;

FIG. 12 is a figure describing a data display process according to Embodiment 2; and

FIG. 13 is a configuration diagram of the development assistance device 10 according to Variation 3.

### DESCRIPTION OF EMBODIMENTS

### Embodiment 1

### ***Description of Configuration***

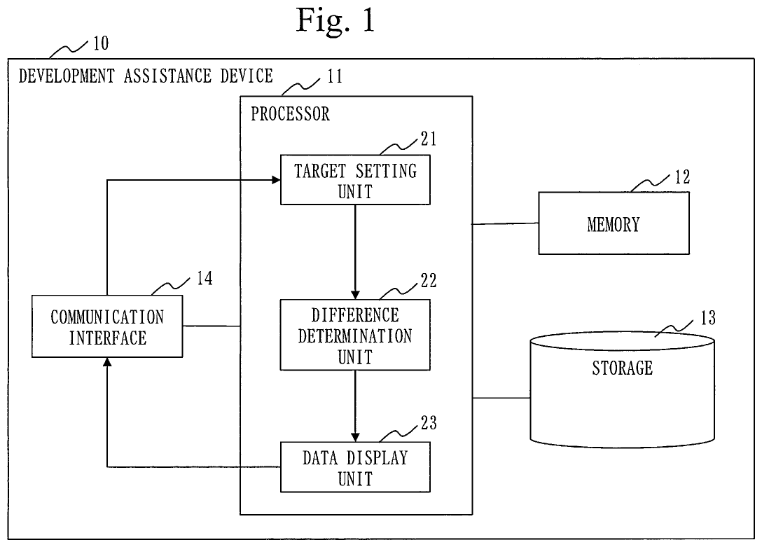

Referring to FIG. 1, a configuration of a development assistance device 10 according to Embodiment 1 will be described.

The development assistance device 10 is a computer.

The development assistance device 10 includes hardware of a processor 11, a memory 12, a storage 13, and a communication interface 14. The processor 11 is connected with other hardware components through signal lines and controls these other hardware components.

The processor 11 is an IC that performs processing. IC is an abbreviation for integrated circuit. Specific examples of the processor 11 are a CPU, a DSP, and a GPU. CPU is an abbreviation for central processing unit. DSP is an abbreviation for digital signal processor. GPU is an abbreviation for graphics processing unit.

The memory 12 is a storage device to temporarily store data. Specific examples of the memory 12 are an SRAM and a DRAM. SRAM is an abbreviation for static random access memory. DRAM is an abbreviation for dynamic random access memory.

The storage 13 is a storage device to store data. A specific example of the storage 13 is an HDD. HDD is an abbreviation for hard disk drive. Alternatively, the storage 13 may be a portable recording medium such as an SD (registered trademark) memory card, CompactFlash (registered trademark), a NAND flash, a flexible disk, an optical disc, a compact disc, a Blu-ray (registered trademark) disc, and a DVD. SD is an abbreviation for Secure Digital. DVD is an abbreviation for digital versatile disk.

The communication interface 14 is an interface for communicating with external devices. Specific examples of the communication interface 14 are an Ethernet (registered trademark) port, a USB port, and an HDMI (registered trademark) port. USB is an abbreviation for Universal Serial Bus. HDMI is an abbreviation for High-Definition Multimedia Interface.

The development assistance device 10 includes, as functional components, a target setting unit 21, a difference determination unit 22, and a data display unit 23. The functions of the functional components of the development assistance device 10 are realized by software.

The storage 13 stores programs that realize the functions of the functional components of the development assistance device 10. These programs are read into the memory 12 by the processor 11 and executed by the processor 11. This realizes the functions of the functional components of the development assistance device 10.

In FIG. 1, only one processor 11 is illustrated. However, there may be a plurality of processors 11, and the plurality of processors 11 may cooperate to execute the programs that realize the functions.

### ***Description of Operation***

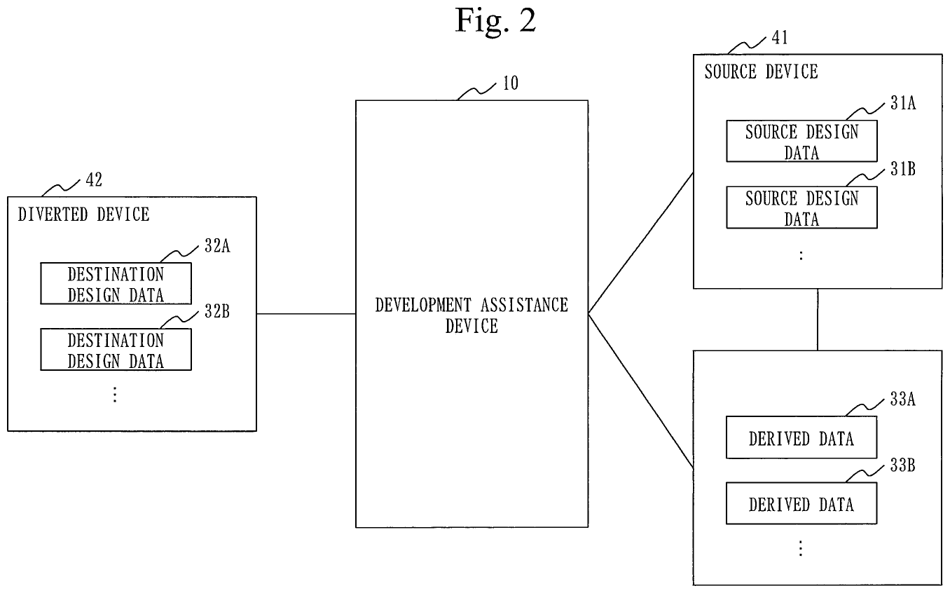

Referring to FIGS. 2 to 9, operation of the development assistance device 10 according to Embodiment 1 will be described.

A procedure for the operation of the development assistance device 10 according to Embodiment 1 is equivalent to a development assistance method according to Embodiment 1. A program that realizes the operation of the development assistance device 10 according to Embodiment 1 is equivalent to a development assistance program according to Embodiment 1.

As illustrated in FIG. 2, a plurality of pieces of source design data 31, a plurality of pieces of destination design data 32, and a plurality of pieces of derived data 33 are given to the development assistance device 10.

The source design data 31 and the destination design data 32 are design data of devices. Specific examples of design data include 3D-CAD design data, electrical CAD data, program design data, and screen design data. CAD is an abbreviation for computer-aided design. The 3D-CAD design data defines a mechanical configuration of a device, sizes of parts, or the like. The electrical CAD data defines a layout of electrical wiring or electrical equipment. The program design data defines a configuration of a program for controlling the operation of a device. The program itself may be included in the design data. The screen design data defines a configuration of an operation screen of a device and so on.

The data format of design data may be a text format that can be checked by humans or may be a data file that can be read only by dedicated software. An example of the text format that can be checked by humans is the STEP file format defined by ISO 10303 for CAD data. For control programs, PLCOpen-XML defined by PLCOpen and the like may be pointed out.

The source design data 31 is design data of a source device 41, which is a device used as a base. The destination design data 32 is design data of a diverted device 42 designed by diverting the source device 41. The destination design data 32 is created by changing, adding to, or deleting part of the source design data 31.

It is not always necessary to create the destination design data 32 by actually diverting the source design data 31. After the destination design data 32 is created, it may be associated with the source design data 31 that is similar.

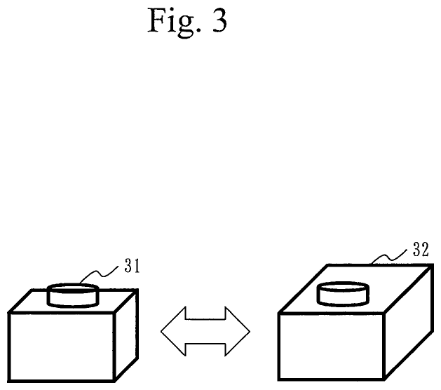

Referring to FIG. 3, an example of the destination design data 32 according to Embodiment 1 will be described. In FIG. 3, data that simulates 3D-CAD design data is indicated. In FIG. 3, the left side represents the source design data 31 of a diversion source, and the right side indicates the destination design data 32 of a diversion destination. The source design data 31 of the diversion source indicates a shape that is a combination of a rectangular parallelepiped and a cylinder. The size of the rectangular parallelepiped indicated by the source design data 31 is changed at the time of diversion. As a result, the destination design data 32 is generated.

The derived data 33 is data derived from the source design data 31. The derived data 33 is mainly data that is delivered to a customer who has purchased the source device 41. A specific example of the derived data 33 is data obtained by removing data other than an external appearance from 3D-CAD data that is the source design data 31. This data is used by the customer to design a location where the device is placed in a factory. Another specific example of the derived data 33 is a manual obtained by adding a main usage method to screen design data that is the source design data 31.

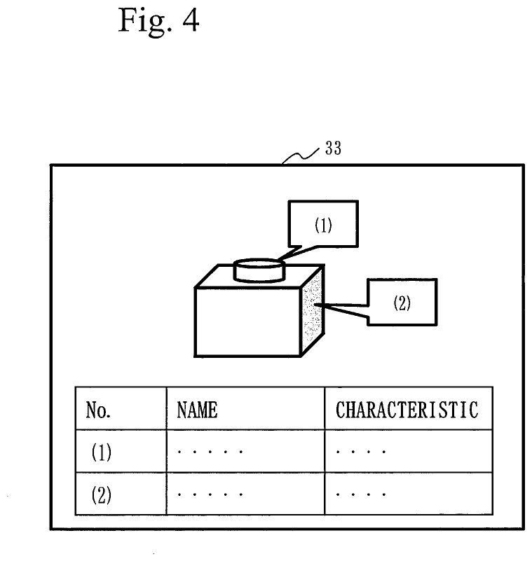

Referring to FIG. 4, an example of the derived data 33 according to Embodiment 1 will be described. FIG. 4 indicates a manual created by being derived from the 3D-CAD data that is the source design data 31 indicated in FIG. 3. This manual indicates an explanation of each part that forms the source device 41. In FIG. 4, the manual that is the derived data 33 is created by adding the explanation to the 3D-CAD data that is the source design data 31.

The source design data 31 of a diversion source and the destination design data 32 of a diversion destination are associated with each other. The source design data 31 of a derivation source and the derived data 33 of a derivation destination are associated with each other.

Associations are made using types of data and names of parts or steps that are constituents of target devices, for example. The types of data are 3D-CAD data, program design data, and so on. The names of parts are turntable and so on. Associations may be made using IDs assigned to individual pieces of data. ID is an abbreviation for identifier. Associations may be made in units of data files, or may be made in units of objects in data files, or chapters or sections of text in data files. Information indicating an association may be included in data, a data name, or a file name. Information indicating an association may be managed in a different file based on the file name or the like.

In FIG. 2, only one source device 41 is indicated. However, the source design data 31 regarding a plurality of source devices 41 may be managed, as in general PLM software.

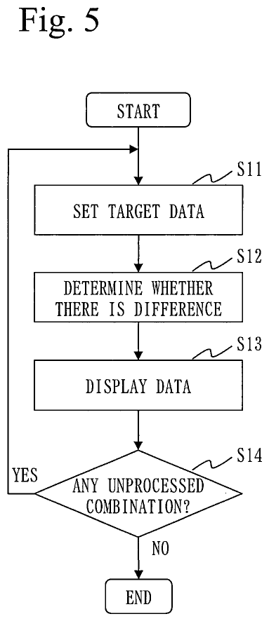

Referring to FIG. 5, a flow of the operation of the development assistance device 10 according to Embodiment 1 will be described.

### (Step S11: Target Setting Process)

The target setting unit 21 sets one of a plurality of pieces of the source design data 31 as the target source design data 31. The target setting unit 21 sets the destination design data 32 associated with the target source design data 31 among a plurality of pieces of the destination design data 32 as the target destination design data 32.

### (Step S12: Difference Determination Process)

The difference determination unit 22 determines whether there is a difference between the target source design data 31 set in step S11 and the target destination design data 32 set in step S11. Specifically, the difference determination unit 22 determines whether there is a difference, based on whether the target source design data 31 and the target destination design data 32 completely match. The difference determination unit 22 may determine whether there is a difference, based on whether the update date and time of the target source design data 31 and the update date and time of the target destination design data 32 match.

If it is determined that there is a difference, the difference determination unit 22 identifies where the difference is located between the target source design data 31 and the target destination design data 32. Specifically, the difference determination unit 22 identifies where the difference is located by comparing the target source design data 31 with the target destination design data 32 on a per object basis. The difference determination unit 22 may identify where the difference is located by detecting setting information of objects and comparing items such as shapes and sizes of objects.

For example, it is assumed that each of the source design data 31 and the destination design data 32 includes 3D-CAD data, electrical CAD data, and program design data. It is assumed here that the source design data 31 and the destination design data 32 are associated through the same type of data. That is, the source design data 31 of 3D-CAD data and the destination design data 32 of 3D-CAD data are associated. The source design data 31 of electrical CAD data and the destination design data 32 of electrical CAD data are associated. The source design data 31 of program design data and the destination design data 32 of program design data are associated.

It is assumed that when the diverted device 42 is designed by diverting the source device 41, only the external shape is changed. In this case, only the 3D-CAD data is changed. That is, when the destination design data 32 is created by diverting the source design data 31, the destination design data 32 is created by making changes only to the 3D-CAD data. No changes are made to the electrical CAD data and the program design data, and they are directly used as the destination design data 32.

Therefore, if the 3D-CAD data is set as each of the target source design data 31 and the target destination design data 32, the difference determination unit 22 determines that there is a difference. If the electrical CAD data or the program design data is set as each of the target source design data 31 and the target destination design data 32, the difference determination unit 22 determines that there is no difference.

For the 3D-CAD data that has been determined to include a difference, the difference determination unit 22 identifies where the difference is located. For example, it is assumed that there is a difference as indicated in FIG. 3. In this case, the difference determination unit 22 may simply identify that the difference in a combination of a rectangular parallelepiped and a cylinder as a whole. The difference determination unit 22 may perform a comparison for each object set in the 3D-CAD data, and identify that the difference is in the shape of a rectangular parallelepiped.

### (Step S13: Data Display Process)

The data display unit 23 displays target data including the target source design data 31, the target destination design data 32, and the derived data 33 generated by making changes to the target source design data 31. At this time, the data display unit 23 changes the display format of the target data, depending on whether it has been determined in step S12 that there is a difference.

Specifically, if it has been determined in step S12 that there is no difference, the data display unit 23 displays that the derived data 33 created from the target source design data 31 can be directly used as destination derived data for the target destination design data 32. The destination derived data is data derived and generated from the destination design data 32. This is based on the idea that if no changes have been made to the destination design data 32, there is no need to make changes to the derived data 33. At this time, the data display unit 23 may display details of the target data, or may display only the file name.

If it has been determined in step S12 that there is a difference, the data display unit 23 displays that the destination derived data for the target destination design data 32 needs to be created by making changes to the derived data 33 created from the target source design data 31. At this time, the data display unit 23 displays information necessary for changes for the target data.

There are methods 1 and 2 below as methods for displaying information necessary for changes. The data display unit 23 may perform display using one of the methods 1 and 2. The data display unit 23 may perform display using both the methods 1 and 2.

### (Method 1)

The data display unit 23 displays the target source design data 31 and the target destination design data 32 with the difference between the target source design data 31 and the target destination design data 32 being indicated, and also displays the derived data 33 created from the target source design data 31. That is, the data display unit 23 displays the difference between the target source design data 31 and the target destination design data 32, and also displays the derived data 33.

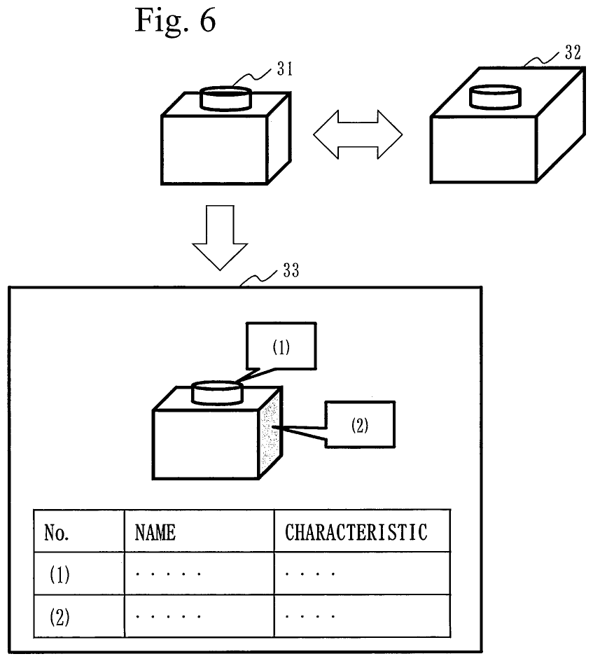

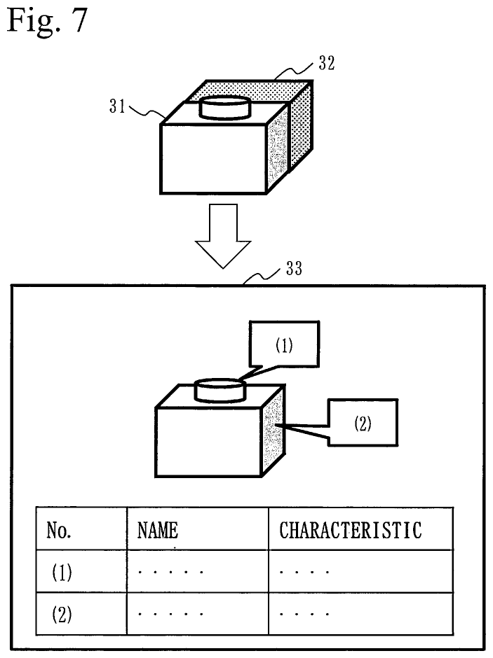

For example, it is assumed that the source design data 31 and the destination design data 32 indicated in FIG. 3 and the derived data 33 indicated in FIG. 4 are given. In this case, as illustrated in FIG. 6, the data display unit 23 displays the source design data 31 and the destination design data 32 side by side to indicate the difference, and also displays the derived data 33. Alternatively, as illustrated in FIG. 7, the data display unit 23 may superimpose the destination design data 32 on the source design data 31 and indicate the difference by hatching or the like, and also display the derived data 33.

This makes it possible to consider changes to the derived data 33 while checking the difference between the source design data 31 and the destination design data 32.

### (Method 2)

The data display unit 23 displays the target source design data 31 and the derived data 33 with the difference between the target source design data 31 the derived data 33 created from the target source design data 31 being indicated, and also displays the target destination design data 32. That is, the data display unit 23 displays the difference between the target source design data 31 and the derived data 33, and also displays the target destination design data 32.

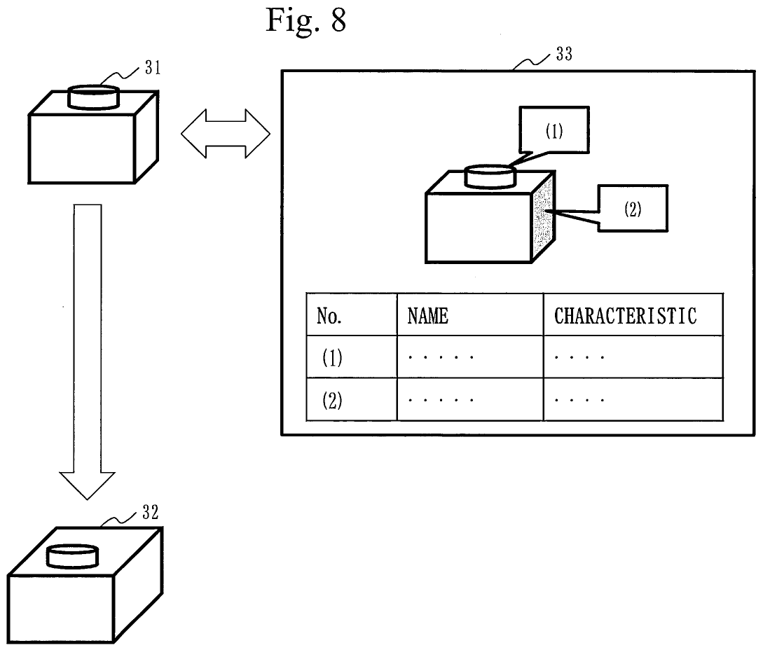

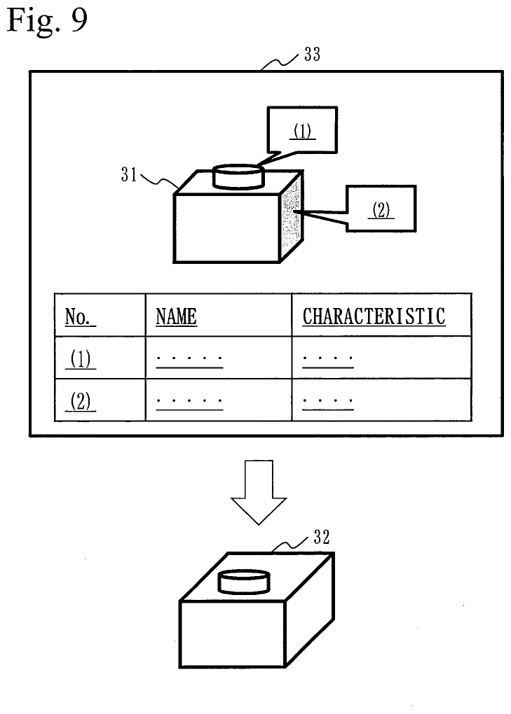

For example, it is assumed that the source design data 31 and the destination design data 32 indicated in FIG. 3 and the derived data 33 indicated in FIG. 4 are given. As illustrated in FIG. 8, the data display unit 23 displays the source design data 31 and the derived data 33 together to indicate the difference, and also displays the destination design data 32. Alternatively, as illustrated in FIG. 9, the data display unit 23 may superimpose the derived data 33 on the source design data 31 and indicate the difference by underlines or the like, and also display the destination design data 32.

This makes it possible to consider changes to the destination design data 32 while checking the difference between the source design data 31 and the derived data 33.

It is conceivable to use the method 1 or 2 depending on whether the destination derived data for the destination design data 32 is to be created from the destination design data 32 or to be created from the derived data 33. When the destination derived data for the destination design data 32 is to be created from the derived data 33 for the source design data 31, the method 1 is suitable. When the destination derived data for the destination design data 32 is to be created from the destination design data 32, the method 2 is suitable.

### (Step S14: Termination Determination Process)

The target setting unit 21 determines whether there remains an unprocessed combination of the source design data 31 of the source device 41 and the destination design data 32 of the diverted device 42. If there remains an unprocessed combination, the target setting unit 21 returns the process to step S11. If there remains no unprocessed combination, the target setting unit 21 terminates the process.

### Effects of Embodiment 1

As described above, the development assistance device 10 according to Embodiment 1 changes the display format, depending on whether there is a difference between the source design data 31 and the destination design data 32. This makes it possible to easily determine whether the derived data 33 for the source design data 31 can be used without changes when the destination derived data for the destination design data 32 is generated. Therefore, the time and effort required to generate the destination derived data can be reduced.

If there is a difference, the development assistance device 10 according to Embodiment 1 displays the derived data 33 with the difference between the source design data 31 and the destination design data 32 being indicated. Alternatively, if there is a difference, the development assistance device 10 according to Embodiment 1 displays the destination design data 32 with a difference between the source design data 31 and the derived data 33 being indicated. This makes it possible to easily identify details of changes to be made when the destination derived data for the destination design data 32 is created. Therefore, the time and effort required to generate the destination derived data can be reduced.

### Other Configurations

### <Variation 1>

In Embodiment 1, the functional components are realized by software. However, as Variation 1, the functional components may be realized by hardware. With regard to this Variation 1, differences from Embodiment 1 will be described.

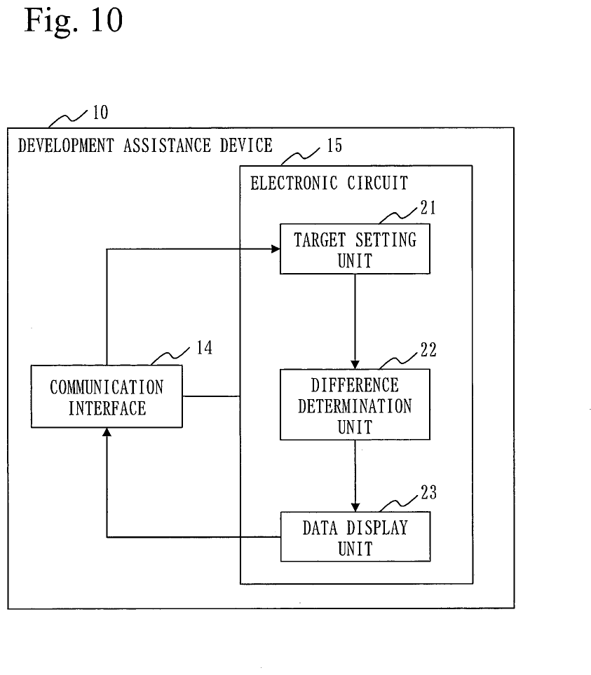

Referring to FIG. 10, a configuration of the development assistance device 10 according to Variation 1 will be described.

When the functional components are realized by hardware, the development assistance device 10 includes an electronic circuit 15 in place of the processor 11, the memory 12, and the storage 13. The electronic circuit 15 is a dedicated circuit that realizes the functions of the functional components, the memory 12, and the storage 13.

The electronic circuit 15 is assumed to be a single circuit, a composite circuit, a programmed processor, a parallel-programmed processor, a logic IC, a GA, an ASIC, or an FPGA. GA is an abbreviation for gate array. ASIC is an abbreviation for application specific integrated circuit. FPGA is an abbreviation for field-programmable gate array.

The functional components may be realized by one electronic circuit 15, or the functional components may be distributed to and realized by a plurality of electronic circuits 15.

### <Variation 2>

As Variation 2, some of the functional components may be realized by hardware, and the rest of the functional components may be realized by software.

Each of the processor 11, the memory 12, the storage 13, and the electronic circuit 15 is referred to as processing circuitry. That is, the functions of the functional components are realized by the processing circuitry.

### Embodiment 2

Embodiment 2 differs from Embodiment 1 in that the source design data 31 includes public discrimination information that indicates non-public information. In Embodiment 2, this difference will be described, and description of the same aspects will be omitted.

Device manufacturers need to keep their know-how confidential even from customers. Therefore, it is necessary to present information required by a customer while hiding information that needs to be kept confidential. It is difficult to determine what needs to be kept confidential. In some cases, designers consult with their superiors or the like to identify information that needs to be kept confidential. Therefore, it takes time and effort to determine what needs to be kept confidential each time derived data is generated.

### ***Description of Configuration***

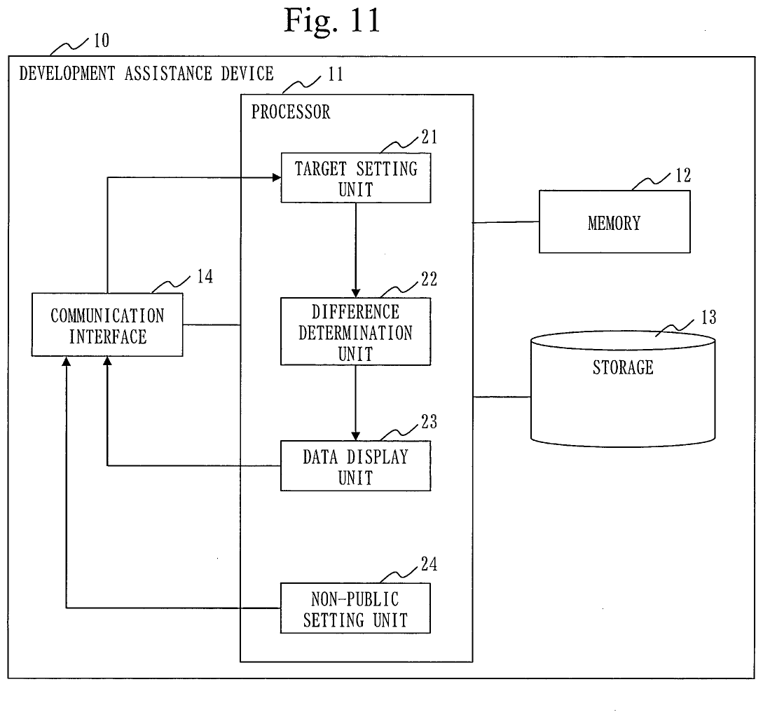

Referring to FIG. 11, a configuration of the development assistance device 10 according to Embodiment 2 will be described.

The development assistance device 10 differs from the development assistance device 10 indicated in FIG. 1 in that a non-public setting unit 24 is included as a functional component. The functions of the non-public setting unit 24 are realized by software or hardware, like the other functional components.

### ***Description of Operation***

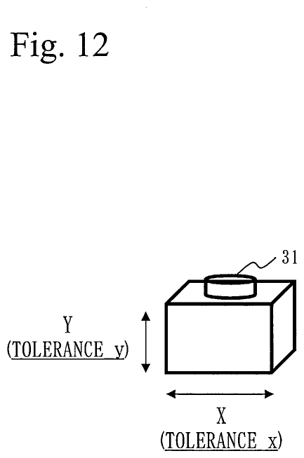

Referring to FIG. 12, operation of the development assistance device 10 according to Embodiment 2 will be described.

A procedure for the operation of the development assistance device 10 according to Embodiment 2 is equivalent to a development assistance method according to Embodiment 2. A program that realizes the operation of the development assistance device 10 according to Embodiment 2 is equivalent to a development assistance program according to Embodiment 2.

The non-public setting unit 24 sets public discrimination information for the source design data 31 according to an operation of a designer. The public discrimination information indicates non-public information that is to be kept non-public among information included in the source design data 31. The non-public setting unit 24 sets the public discrimination information in the source design data 31 when the source device 41 is designed or when the derived data 33 concerning the source device 41 is created.

The non-public information is, for example, a tolerance setting that indicates a difference between the maximum and minimum dimensions of a size allowable error when parts of the source device 41 are produced. If the tolerance setting is to be set as non-public, the non-public setting unit 24 sets the public discrimination information in which a data type “tolerance setting” is specified for 3D-CAD data that is the source design data 31 of a target part. Alternatively, the non-public setting unit 24 may set the public discrimination information in which the tolerance setting for each piece of dimension information is specified for the 3D-CAD data of the target part. Alternatively, the non-public setting unit 24 may set the public discrimination information in which text information such as “tolerance setting is to be non-public” is specified for the 3D-CAD data of the target part.

Referring to FIG. 5, a flow of the operation of the development assistance device 10 according to Embodiment 2 will be described.

The processes of steps S11, S12, and S14 are the same as those in Embodiment 1.

### (Step S13: Data Display Process)

The data display unit 23 displays the target data, as in Embodiment 1. At this time, if the public discrimination information is set in the target source design data 31, the data display unit 23 displays the public discrimination information together with the target source design data 31.

The data display unit 23 displays the public discrimination information in a manner that corresponds to how the public discrimination information is set. For example, if the public discrimination information specifies a data type, the data display unit 23 displays text information or the like indicating that the specified data type is non-public information. If the public discrimination information specifies text information, the data display unit 23 directly displays the specified text information. If the public discrimination information specifies the tolerance setting for each piece of dimension information, the data display unit 23 displays underlines or the like for emphasis under the tolerance setting corresponding to each piece of dimension information, as indicated in FIG. 12.

### Effects of Embodiment 2

As described above, the development assistance device 10 according to Embodiment 2 displays the public discrimination information together with the source design data 31. This makes it possible to easily identify which information is to be kept confidential when the destination derived data for the destination design data 32 is created. For example, when tolerance information is set as non-public information, it can be easily determined that the tolerance information needs to be deleted when the destination derived data is generated. Therefore, the time and effort required to generate the destination derived data can be reduced.

### Other Configurations

### <Variation 3>

The destination derived data for the destination design data 32 may be automatically generated.

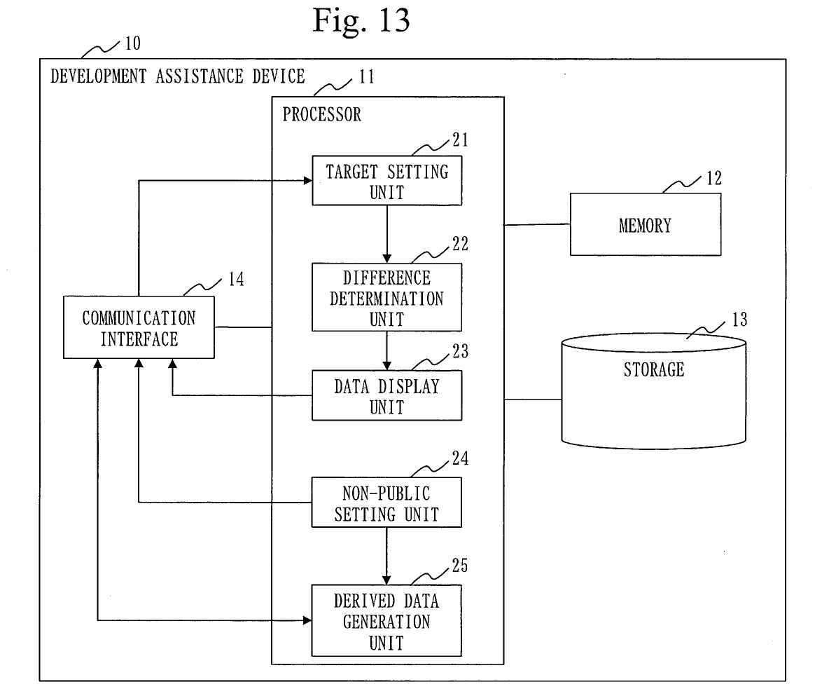

In this case, the development assistance device 10 includes a derived data generation unit 25 as a functional component, as illustrated in FIG. 13. The functions of the derived data generation unit 25 are realized by software or hardware, like the other functional components.

The derived data generation unit 25 generates the destination derived data for the destination design data 32 by deleting non-public information indicated by the public discrimination information from the destination design data 32. As described above, derived data needs to be generated by deleting non-public information. The destination design data 32 may also be used as the source of the derived data 33. Therefore, by generating the destination derived data by deleting the non-public information from the destination design data 32, the time and effort required to create the destination derived data can be reduced.

“Unit” in the above description may be interpreted as “circuit”, “step”, “procedure”, “process”, or “processing circuitry”.

The embodiments and variations of the present disclosure have been described above. Two or more of these embodiments and variations may be implemented in combination. Alternatively, one of them or two or more of them may be partially implemented. The present disclosure is not limited to the above embodiments and variations, and various modifications can be made as necessary.

### REFERENCE SIGNS LIST

10: development assistance device, 11: processor, 12: memory, 13: storage, 14: communication interface, 15: electronic circuit, 21: target setting unit, 22: difference determination unit, 23: data display unit, 24: non-public setting unit, 25: derived data generation unit, 31: source design data, 32: destination design data, 33: derived data, 41: source device, 42: diverted device.

1. A development assistance device comprising
processing circuitry to:
determine whether there is a difference between source design data and destination design data associated with the source design data; and
display target data including the source design data, the destination design data, and derived data generated by making a change to the source design data, change a display format of the target data, depending on whether it has been determined that there is a difference, and when it has been determined that there is a difference, display the source design data and the derived data with a difference between the source design data and the derived data being indicated, and also display the destination design data.

2. The development assistance device according to claim 1,
wherein when it has been determined that there is a difference, the processing circuitry displays the source design data and the destination design data with the difference between the source design data and the destination design data being indicated, and also displays the derived data.

3. The development assistance device according to claim 1,
wherein the source design data is design data of a source device, and
wherein the destination design data is design data of a diverted device designed by diverting the source device.

4. The development assistance device according to claim 2,
wherein the source design data is design data of a source device, and
wherein the destination design data is design data of a diverted device designed by diverting the source device.

5. The development assistance device according to claim 1,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

6. The development assistance device according to claim 2,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

7. The development assistance device according to claim 3,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

8. The development assistance device according to claim 4,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

9. A development assistance method comprising:
determining whether there is a difference between source design data and destination design data associated with the source design data; and
displaying target data including the source design data, the destination design data, and derived data generated by making a change to the source design data, changing a display format of the target data, depending on whether it has been determined that there is a difference, and when it has been determined that there is a difference, displaying the source design data and the derived data with a difference between the source design data and the derived data being indicated, and also displaying the destination design data.

10. A non-transitory computer readable medium storing a development assistance program that causes a computer to function as a development assistance device to perform:
a difference determination process of determining whether there is a difference between source design data and destination design data associated with the source design data; and
a data display process of displaying target data including the source design data, the destination design data, and derived data generated by making a change to the source design data, the data display process changing a display format of the target data, depending on whether it has been determined by the difference determination process that there is a difference, and when it has been determined that there is a difference, displaying the source design data and the derived data with a difference between the source design data and the derived data being indicated, and also displaying the destination design data.

11. A development assistance device comprising
processing circuitry to:
determine whether there is a difference between source design data and destination design data associated with the source design data, the source design data including public discrimination information that indicates non-public information to be kept non-public among information included in the source design data;
display target data including the source design data, the destination design data, and derived data generated by making a change to the source design data, change a display format of the target data, depending on whether it has been determined that there is a difference, and display the public discrimination information together with the source design data; and
generate destination derived data corresponding to the destination design data by deleting the non-public information indicated by the public discrimination information from the destination design data.

12. The development assistance device according to claim 11,
wherein when it has been determined that there is a difference, the processing circuitry displays the source design data and the destination design data with the difference between the source design data and the destination design data being indicated, and also displays the derived data.

13. The development assistance device according to claim 11,
wherein the source design data is design data of a source device, and
wherein the destination design data is design data of a diverted device designed by diverting the source device.

14. The development assistance device according to claim 12,
wherein the source design data is design data of a source device, and
wherein the destination design data is design data of a diverted device designed by diverting the source device.

15. The development assistance device according to claim 11,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

16. The development assistance device according to claim 12,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

17. The development assistance device according to claim 13,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

18. The development assistance device according to claim 14,
wherein the processing circuitry sets one piece of source design data selected from a plurality of pieces of source design data as target source design data, and sets destination design data associated with the target source design data as target destination design data, and
wherein the processing circuitry determines whether there is a difference between the target source design data and the target destination design data.

19. A development assistance method comprising:
determining whether there is a difference between source design data and destination design data associated with the source design data, the source design data including public discrimination information that indicates non-public information to be kept non-public among information included in the source design data;
displaying target data including the source design data, the destination design data, and derived data generated by making a change to the source design data, changing a display format of the target data, depending on whether it has been determined that there is a difference, and displaying the public discrimination information together with the source design data; and
generating destination derived data corresponding to the destination design data by deleting the non-public information indicated by the public discrimination information from the destination design data.

20. A non-transitory computer readable medium storing a development assistance program that causes a computer to function as a development assistance device to perform:
a difference determination process of determining whether there is a difference between source design data and destination design data associated with the source design data, the source design data including public discrimination information that indicates non-public information to be kept non-public among information included in the source design data;
a data display process of displaying target data including the source design data, the destination design data, and derived data generated by making a change to the source design data, the data display process changing a display format of the target data, depending on whether it has been determined by the difference determination process that there is a difference, and displaying the public discrimination information together with the source design data; and
a derived data generation process of generating destination derived data corresponding to the destination design data by deleting the non-public information indicated by the public discrimination information from the destination design data.
